(19) United States
(12) Patent Application Publication
(10) Pub. No.: US 2018/0097335 A1
(43) Pub. Date: Apr. 5, 2018

(54) OPTOELECTRONIC LAMP DEVICE

(71) Applicant: OSRAM Opto Semiconductors GmbH, Regensburg (DE)

(72) Inventors: Andreas Breidenassel, Bad Abbach (DE); Roland Enzmann, Regensburg (DE); Sergey Khrushchev, Regensburg (DE)

(21) Appl. No.: 15/566,575

(22) PCT Filed: Apr. 15, 2016
(86) PCT No.: PCT/EP2016/058387

§ 371 Date: Oct. 13, 2017

(30) Foreign Application Priority Data
Apr. 16, 2015 (DE) 10 2015 105 807.3

(51) Int. Cl. H01S 5/022; G02B 19/00; G02B 27/30

(52) U.S. Cl. CPC H01S 5/02236; G02B 27/30; G02B 19/0057

(57) ABSTRACT

An optoelectronic lamp device, including a carrier having a planar mounting face, at least one laser diode that emits laser radiation, wherein the laser diode has a fast axis and a slow axis, the laser diode is arranged on the mounting face such that the fast axis is formed extending parallel to the mounting face, a first collimator is provided for collimating laser radiation polarized in the direction of the fast axis, and a second collimator is provided for collimating laser radiation polarized in the direction of the slow axis, wherein, in the beam path of the laser radiation emitted by the laser diode, the first collimator is arranged proximally and the second collimator is arranged distally relative to the laser diode so that the laser radiation polarized in the direction of the fast axis can be collimated first, and only then can the laser radiation polarized in the direction of the slow axis be collimated.

### TECHNICAL FIELD

This disclosure relates to an optoelectronic lamp device.

To implement a highly integrated laser module, laser chips may be mounted either in a planar fashion directly on a carrier substrate or via a heat spreader. In conventional planar mounting of laser diodes, the height of the facet above the mounting plate is undetermined within certain tolerances (a few tens of μm because of substrate thickness variation, or alternatively height variation of the submount). If an optical element is desired to be used for collimation of the laser radiation, particularly for use in micro-optics, the problem arises that the emission direction of the laser beam and the optical axis of the collimation lens cannot easily be superimposed. The desired superimposition makes accurate adjustment of the collimation lens very elaborate since (besides further axes) it also needs to be adjusted heightwise.

The problem has previously been resolved by active adjustment of the lens over a plurality of degrees of freedom. In that case, for example, adhesive bonding, resistive soldering or solder-jet soldering may be envisioned as a mounting technology. Depending on the accuracy requirement, this is a very elaborate process. In connection with degassing-sensitive laser diodes (for example blue, 450 nm), the use of adhesives in the same housing is prohibited, which makes implementation even more difficult.

It could therefore be helpful to provide an efficient and simple adjustment of collimators to efficiently collimate laser radiation emitted by a laser diode.

### SUMMARY

We provide an optoelectronic lamp device, including a carrier having a planar mounting face, at least one laser diode that emits laser radiation, wherein the laser diode has a fast axis and a slow axis, the laser diode is arranged on the mounting face such that the fast axis is formed extending parallel to the mounting face, a first collimator is provided for collimating laser radiation polarized in the direction of the fast axis and, a second collimator is provided for collimating laser radiation polarized in the direction of the slow axis, wherein, in the beam path of the laser radiation emitted by the laser diode, the first collimator is arranged proximally and the second collimator is arranged distally relative to the laser diode so that the laser radiation polarized in the direction of the fast axis can be collimated first, and only then can the laser radiation polarized in the direction of the slow axis be collimated.

### BRIEF DESCRIPTION OF DRAWINGS

FIG. 1 shows an optoelectronic lamp device in an oblique plan view.

FIG. 2 shows a view from below of the optoelectronic lamp device of FIG. 1.

FIG. 3 shows a detail view of the optoelectronic lamp device of FIG. 1.

FIG. 4 shows an electrical contacting possibility between a subcarrier and a carrier.

### LIST OF REFERENCES

101 optoelectronic lamp device

103 carrier

105 mounting face

107 subcarrier

109 subcarrier

111 subcarrier

113 red laser diode

115 green laser diode

117 blue laser diode

119 coordinate system

121, 125, 129 first collimator

123, 127, 131 second collimator

133 deviating optics

135 housing

137 NTC temperature sensor

139 conductor tracks

141 electrical contacts

143, 145, 147 laser radiation

201, 203, 205 first surface

207, 209, 211 second surface

301 third electrical contact pad

303 anode

305 bonding wire

401 subcarrier

403 first surface

405 second surface

407, 409 layer arrangement

411 laser diode

413 first electrical contact pad

415 second electrical contact pad

417 third electrical contact pad

419 solder ball

421 anode

423 bonding wire

425 height

427 edge distance

429 edge

431 width

### DETAILED DESCRIPTION

Our optoelectronic lamp device may comprise:
a carrier having a planar mounting face,
at least one laser diode for emitting laser radiation, wherein
the laser diode has a fast axis and a slow axis,
wherein the laser diode is arranged on the mounting face in such a way that the fast axis is formed extending parallel to the mounting face,
wherein a first collimator is provided for collimating laser radiation polarized in the direction of the fast axis and
a second collimator is provided for collimating laser radiation polarized in the direction of the slow axis,
wherein, in the beam path of the laser radiation emitted by means of the laser diode, the first collimator is arranged proximally and the second collimator is arranged distally relative to the laser diode, so that
the laser radiation polarized in the direction of the fast axis can be collimated first, and only then can the laser radiation polarized in the direction of the slow axis be collimated.

Our device thus comprises, in particular, arranging the laser diode on the mounting face such that the fast axis extends parallel to the mounting face. Furthermore, we provide that a functionality of a collimation be divided between two collimators. The two collimators are thus respectively used for so-called “Fast Axis” Collimation (FAC) and for so-called “Slow Axis” Collimation (SAC). This thus means, in particular, that the laser radiation polarized in the direction of the fast axis is collimated first, and only then is the laser radiation polarized in the direction of the slow axis collimated, by the corresponding collimators.

Because the laser diode must be arranged or mounted on the mounting face such that the fast axis is formed extending parallel to the mounting face, in particular the technical advantage is achieved that the first collimator can be aligned in a simply implementable planar (in relation to the mounting face) adjustment process. For the purpose of collimation, the first collimator therefore only needs to be adjusted parallel to the mounting face. Because of this, the first collimator can be aligned or adjusted particularly precisely. This is in contrast to the previously conventional case that the first collimator needed to be adjusted heightwise perpendicularly to the mounting face. This is because precise alignment of the collimator in the height direction is elaborate and difficult since the individual components (for example, laser diode, possibly a subcarrier) have height tolerances in the range of from a few μm to 10 μm, particularly in the region of 10 μm, for example, up to 20 μm.

Furthermore, as known because of the high laser beam divergence combined with the difficult height adjustment, it has previously been necessary to arrange the collimator very close to the laser facet. Such a close arrangement is therefore no longer necessary. Because of this, mounting and adjustment of the first collimator is made easier.

The effect achieved by this special arrangement of the laser diode on the mounting face is, in particular, that a problem of height adjustment is shifted to the second collimator. Yet for this, tolerance requirements are much easier to satisfy than for the first collimator. This is because a divergence angle of a laser diode in relation to the slow axis is generally much smaller or less than a divergence angle of the laser diode in relation to the fast axis (generally by a factor of from 2 to 5). If a target of a circular spot after collimation by the two collimators is assumed, there is correspondingly a greater distance of the second collimator from a facet of the laser diode so that tolerance requirements are reduced by the same factor. The facet refers to the exit face of the laser diode, through which laser radiation is emitted. A laser diode in the context of the present invention comprises, in particular, a laser facet.

The fast axis of the laser diode refers, in particular, to an axis parallel to a crystal growth direction of a laser crystal (or of a laser crystal layer) of the laser diode.

The slow axis of the laser diode refers, in particular, to an axis perpendicular to the crystal growth direction of the laser crystal (or of a laser crystal layer) of the laser diode, i.e. in particular parallel to a plane of epitaxial layers of the laser diode.

The laser diode comprises, for example, a plurality of layers (epitaxial layers), which are grown by an epitaxy method. At least one of these layers forms a laser crystal layer having a corresponding growth direction.

An exemplary emission angle of the laser radiation at FWHM (“Full Width at Half Maximum”, i.e. width at half height) of the laser intensity is, for example, 10° degrees to 30° degrees relative to the fast axis.

An exemplary emission angle of the laser radiation at FWHM of the laser intensity is, for example, 5° degrees to 15° degrees relative to the slow axis.

The terms “fast axis” and “slow axis” are terms of art and known per se.

The first and/or the second collimator may respectively be configured as a collimator lens, in particular as a cylindrical lens.

In particular, this achieves the technical advantage that efficient collimation of the laser radiation can be brought about.

The laser diode may be arranged on a subcarrier is arranged on the mounting face so that the laser diode is arranged indirectly on the mounting face by the subcarrier.

In particular, this achieves the technical advantage that even better adjustability of a height of a laser facet of the laser diode above the mounting face is in this case made possible. This is because there is in this case no longer a dependency on a given material thickness of a laser substrate of the laser diode. Rather, the laser diode can be mounted or arranged with significantly greater precision on the subcarrier before mounting or arrangement of the subcarrier on the mounting face.

The subcarrier may be formed as a submount.

The subcarrier, in particular the submount, may be configured as a heat sink. This, for example, achieves the technical advantage that heat generated by the laser diode during its operation can be dissipated efficiently.

The subcarrier may be configured as a printed circuit board or as a circuit board. This, in particular, achieves the technical advantage that efficient electrical contacting of the laser diode is made possible.

The carrier may be configured as a printed circuit board or as a circuit board. This, in particular, achieves the technical advantage that efficient electrical contacting of the laser diode is made possible.

The laser diode may be configured as a laser chip.

The laser diode has, in particular, a laser facet. The laser beam is emitted through the laser facet.

A distance of the first collimator from the laser diode (i.e. in particular from the laser facet) may be 0.7 mm to 1.3 mm. This, in particular, for a red or blue or green laser diode.

A distance of the second collimator from the laser diode (i.e. in particular from the laser facet) may be 5.0 mm to 5.5 mm. This, in particular, for a green or blue laser diode.

A distance of the second collimator from the laser diode (i.e. in particular from the laser facet) may be 3.0 mm to 3.5 mm. This, in particular, for a red laser diode.

The distances of the collimators from the laser diode (in particular from the laser facet) depend, in particular, on a desired ellipticity of the collimated laser beam.

The first collimator and the second collimator may form a common collimator component, in particular a common one-piece collimator component, i.e. they are configured as a common collimator component, in particular as a common one-piece collimator component. This, for example, achieves the technical advantage that efficient adjustment can be achieved. This is because only one component then needs to be mounted and adjusted.

Opposite end faces (front side and rear side) of the collimator component may respectively be configured as a cylindrical lens, these being rotated by about 90° degrees relative to one another. This means that collimation is brought about by the cylindrical lenses. Each of the cylindrical lenses thus collimates the laser beam. Because of the 90° rotation, one cylindrical lens brings about collimation of the laser radiation polarized in the direction of the fast axis, and the other cylindrical lens brings about collimation of the laser radiation polarized in the direction of the slow axis.

The formulation “about 90° degrees” also includes those examples in which a deviation from 90° degrees occurs because of manufacturing tolerances. Thus, this formulation also includes a deviation of ±5° degrees, for example.

Provision of the collimator component has, in particular, the advantage that only a single component needs to be placed or mounted with an accurately defined distance of the first and second collimators from the laser diode. This is advantageous, in particular, when requirements for definition of the ellipticity of the collimated laser beam are not too great or narrow, and/or when the laser diodes have a particular divergence ratio in relation to the emitted laser beam, for example because the laser diodes have been pre-sorted before they are mounted on the carrier.

The subcarrier may have a first surface facing toward the mounting face, wherein the laser diode is arranged on a second surface of the subcarrier, which surface is formed perpendicularly to the first surface.

In particular, this achieves the technical advantage that an efficient and simple arrangement of the laser diode can be achieved such that the fast axis is formed extending parallel to the mounting face.

The subcarrier may be configured as a cuboid. This, in particular, achieves the technical advantage that the subcarrier can be produced simply.

The subcarrier may thus be configured in the shape of a cuboid. In this way, for example, the subcarrier can advantageously be produced efficiently.

The subcarrier and/or the carrier may respectively be formed from silicon, or comprise respectively comprises silicon. The use of silicon has, in particular, the technical advantage that the carrier respectively subcarrier can be processed efficiently by known photolithographic processes, for example, to form electrical contacts and/or electrical conductor tracks.

The formulation “respectively” comprises, in particular, the formulation “and/or”.

A first electrical contact pad and a second electrical contact pad may be formed on the carrier, perpendicularly to the second surface, in particular on the mounting face, these contact pads being electrically connected respectively to an anode and to a cathode of the laser diode.

In particular, this achieves the technical advantage that efficient electrical contacting of the anode and of the cathode of the laser diode is made possible. Thus, for example, the anode and the cathode of the laser diode can be electrically contacted by electric contact of the first and of the second electrical contact pads.

A third electrical contact pad, electrically connected to an anode or to a cathode, may be arranged on the second surface, the third electrical contact pad being electrically connected to the first or second electrical contact pad, for example, by solder balls. This thus means, in particular, that the third electrical contact pad electrically connects electrically conductively to the first or to the second electrical contact pad by a solder ball.

The third electrical contact pad may be electrically conductively connect to an anode or a cathode of the laser diode by a bond wire.

An electrical connection between the second or the first electrical contact pad and a cathode or an anode of the laser diode may comprise a solder ball.

The provision of a solder ball advantageously leads to efficient electrical contacting.

This, in particular, achieves the technical advantage that efficient and flexible electrical contacting of the anode or cathode can be achieved. Thus, for example, an accurate position of the laser diode on the second surface may be selected independently of a specific position of the first or second electrical contact pad on the carrier. This is because electrical contacting is established via the third electrical contact pad, which electrically connects to the first or second electrical contact pad.

Deviating optics for deviating laser radiation collimated by the second collimator may be arranged in the beam path.

This, in particular, achieves the technical advantage that flexible laser beam guiding can be achieved. In particular, an existing installation space or mounting space can in this way advantageously be utilized efficiently.

A red laser diode, a green laser diode and a blue laser diode may be provided with respectively assigned first and second collimators so that an RGB laser source is formed.

In particular, this achieves the technical advantage that an RGB laser source is provided. “RGB” stands for “red green blue”. By these three primary colors, generation of a multiplicity of colors by color mixing is advantageously made possible.

The red laser diode, the green laser diode and the blue laser diode may be arranged on a common carrier. This, in particular, achieves the technical advantage that a common defined distance of the laser diodes from the mounting face can be provided.

The red laser diode, the green laser diode and the blue laser diode may respectively be arranged on a separate subcarrier. This, in particular, achieves the technical advantage that flexible and efficient adjustment of the corresponding collimators for the individual laser diodes is made possible.

The comments made in connection with the red, green and blue laser diodes apply similarly for the general case that an optoelectronic lamp device which comprises a plurality of laser diodes is provided.

Therefore, the optoelectronic lamp device may comprise a plurality of laser diodes.

A laser wavelength of the laser radiation may be 450 nm (blue) or lies between 440 nm and 480 nm (blue), in particular 530 nm (green) or lies between 520 nm and 565 nm (green), for example, 630 nm (red) or lies above 600 nm (red). The laser wavelength may, for example, lie in a range of ±15 nm around the aforementioned exemplary values for the laser wavelength.

A red laser diode thus emits red laser radiation. A green laser diode thus emits green laser radiation. A blue laser diode thus emits blue laser radiation.

The carrier and/or the subcarrier may comprise respectively comprise silicon and/or aluminum nitrite. Silicon and aluminum nitrite have, in particular, the technical advantage that photolithography processing of the carrier and of the subcarrier is possible.

The carrier and/or the subcarrier may respectively be processed by a photolithographic process.

The carrier and/or the subcarrier may comprise respectively comprise electrical lines, in particular electrical conductor tracks, and/or electrical contacts, which, for example, according to another example, are produced by a photolithographic method.

The above-described properties, features and advantages, as well as the way in which they are achieved, will become more clearly and readily comprehensible in conjunction with the following description of the examples, which will be explained in more detail in connection with the drawings.

In the following, the same references may be used for identical features.

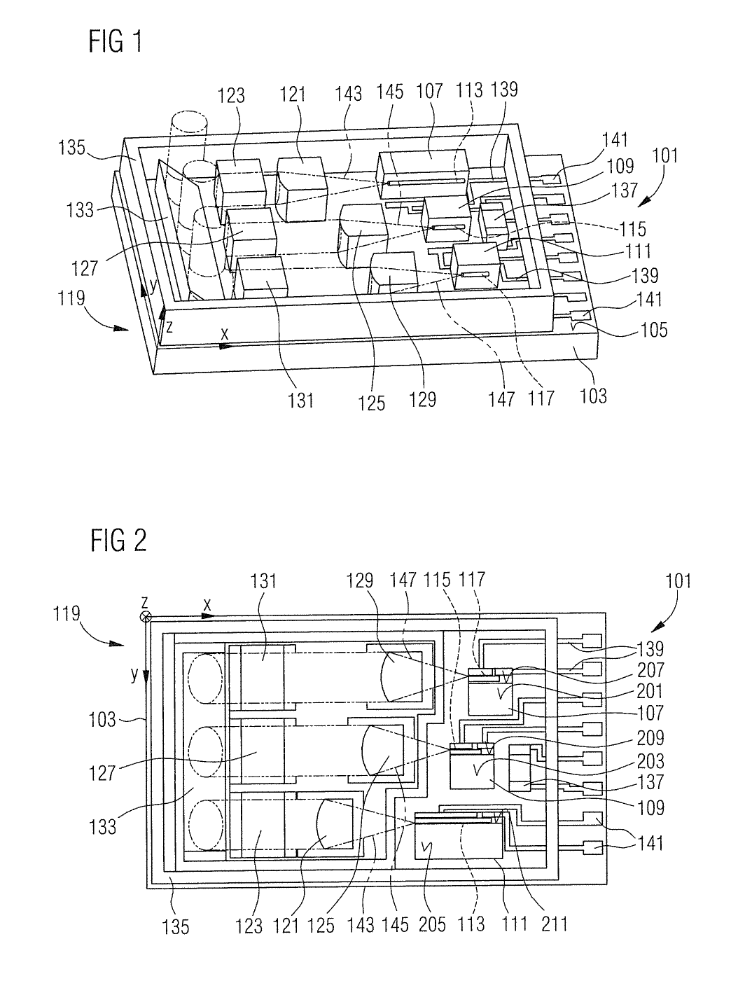

FIG. 1 shows an optoelectronic lamp device 101.

The optoelectronic lamp device 101 comprises a carrier 103 that, for example, may be formed from silicon or from aluminum nitrite or may comprise silicon and/or aluminum nitrite. The carrier 103 may, for example, be configured in general as a mounting plate.

The carrier 103 has a planar mounting face 105. Three subcarriers 107, 109 and 111 are arranged on the mounting face 105. The subcarriers 107, 109, 111 have a cuboid shape. The subcarriers 107, 109, 111 comprise, for example, silicon and/or aluminum nitrite, or are, for example, formed from silicon or from aluminum nitrite. The subcarriers 107, 109, 111 are preferably configured as a submount. In particular, the subcarriers 107, 109, 111 are respectively configured as a printed circuit board.

A laser diode 113, 115, 117 is respectively arranged on the three subcarriers 107, 109, 111. This thus means that the laser diode 113, which is a red laser diode, is arranged on the subcarrier 107. The laser diode 115, which is a green laser diode, is arranged on the subcarrier 109. The laser diode 117, which is configured as a blue laser diode, is arranged on the subcarrier 111. An RGB laser source is therefore provided or formed.

The three laser diodes 113, 115, 117 are therefore arranged indirectly on the mounting face 105 of the carrier 103 by the subcarriers 107, 109, 111. In this case, the laser diodes 113, 115, 117 are arranged on the corresponding subcarriers 107, 109, 111 such that their respective fast axis is formed extending parallel to the mounting face 105. Their respective slow axis is formed extending perpendicularly to the mounting face 105.

For better clarity, a Cartesian coordinate system 119 comprising an x axis, a y axis and a z axis is indicated. The x axis and the y axis thus form an x,y plane, which extends parallel to the mounting face. This thus means that the respective fast axes of the laser diodes 113, 115, 117 extend parallel to the x,y plane.

Respective laser radiation emitted by the laser diodes 113, 115, 117 is symbolically provided with the references 143, 145, 147. This thus means that the red laser radiation emitted by the red laser diode 113, is denoted by the reference 143. The green laser radiation emitted by the green laser diode 115 is symbolically denoted by the reference 145. The blue laser radiation emitted by the blue laser diode 117 is symbolically denoted by the reference 147.

The respective laser radiation 143, 145, 147 is collimated by collimators. To this end, a first collimator 121 and a second collimator 123 are provided in the beam path of the red laser radiation 143. Correspondingly, a first collimator 125 and a second collimator 127 are provided in the beam path of the green laser radiation 145. Correspondingly, a first collimator 129 and a second collimator 131 are provided in the beam path of the blue laser radiation 147.

An order of the first and second collimators is such that the corresponding laser radiation shines first through the first collimator, and only then through the second collimator. In this case, the first collimators 121, 125, 129 are configured to collimate corresponding laser radiation polarized in the direction of the fast axis. The second collimators 123, 127, 131 are configured to collimate the corresponding laser radiation polarized in the direction of the slow axis.

This thus means that the laser radiation polarized in the direction of the fast axis is collimated first, and only then is the laser radiation polarized in the direction of the slow axis collimated.

The first collimators 121, 125, 129 and the second collimators 123, 127, 131 may be cylindrical lenses.

The optoelectronic lamp device 101 furthermore comprises deviating optics 133, for example, in general a deviating mirror, which deviates the laser radiation which respectively shines through the second collimators 123, 127, 131. For example, the deviating optics 133 are configured in order to deviate the laser radiation away from the mounting face 105, for example perpendicularly away from the mounting face 105.

The example according to FIG. 1 shows common deviating optics 133 for the three collimated laser radiations of the laser diodes 113, 115, 117. In one general example (not shown), separate deviating optics may be provided for each collimated laser radiation.

Furthermore, the optoelectronic lamp device 101 comprises a housing 135 that encloses the laser diodes 113, 115, 117 as well as the collimators 121, 123, 125, 127, 129, 131 and the deviating optics 133. In this case, a shape of the housing 135 is, for example, such that it corresponds at least partially to a contour of the carrier 103, in particular of the mounting face 105.

In FIG. 1, the housing 135 is represented as being open upward, i.e. in the z direction. According to one example, the housing 135 may be closed or covered on its open side, for example, hermetically closed or hermetically covered. In this case, in particular, provision is then made for this cover to be at least partially transparent to transmit the collimated and deviated laser radiation. For example, such a cover is fully transparent.

Reference 137 indicates an NTC temperature sensor, which may detect a temperature on the carrier 103 and/or in the housing 135. NTC stands for “negative temperature coefficient”.

Conductor tracks 139 and electrical contacts 141 are furthermore formed on the mounting face 105. Electrical contacting of the laser diodes 113, 115, 117 is advantageously brought about via the electrical contacts 141 and the conductor tracks 139.

FIG. 2 shows a view from below of the optoelectronic lamp device 101 of FIG. 1.

Although in reality a surface of the subcarrier 107, 109, 111 facing toward the mounting face 105 is not visible in a view from below, because of the lack of transparency or the non-transparency of the carrier 103, these surfaces are nevertheless provided with a respective reference. This is for better comprehension and representation.

Thus, reference 201 indicates a first surface of the subcarrier 107 facing toward the mounting face 135. Reference 203 indicates a first surface of the subcarrier 109 facing toward the mounting face 105. Reference 205 indicates a first surface of the subcarrier 111 facing toward the mounting face 105.

Reference 207 indicates a second surface of the subcarrier 107 extending perpendicularly to the first surface 201. The blue laser diode 117 is arranged on this first surface 201.

Reference 209 indicates a second surface of the subcarrier 109 extending perpendicularly to the first surface 203. The green laser diode 115 is arranged on the second surface 209.

Reference 211 indicates a second surface of the subcarrier 111, extending perpendicularly to the first surface 205. The red laser diode 113 is arranged on the second surface 211.

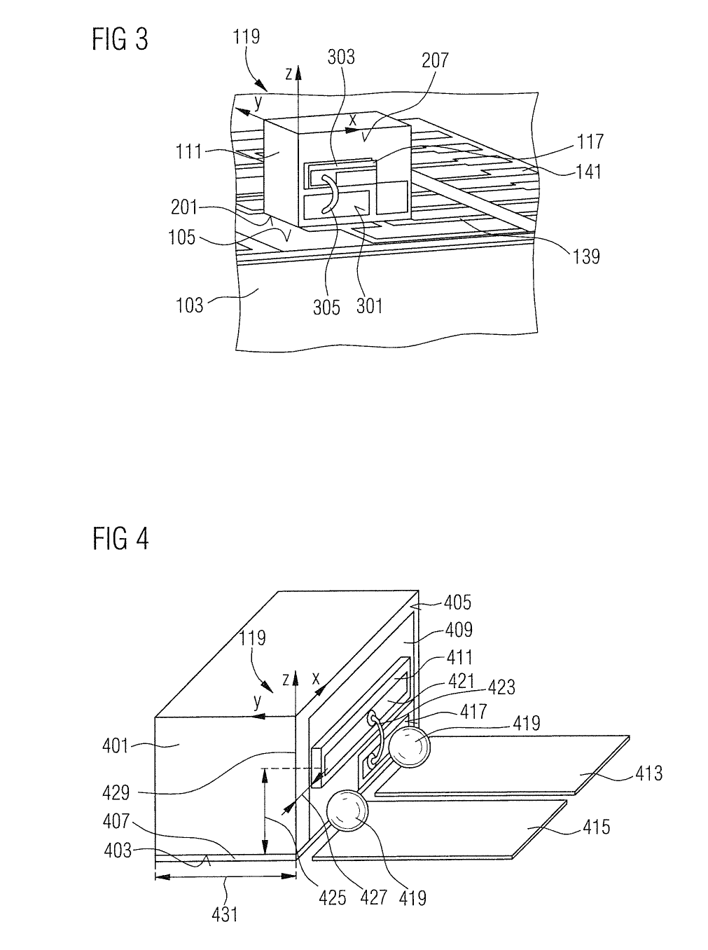

FIG. 3 shows a detail view of the optoelectronic lamp device 101 of FIG. 1.

The detail view shows the blue laser diode 117 arranged on the second surface 207 of the subcarrier 111. For better clarity, the housing 135 is not indicated in FIG. 3.

The detail view furthermore shows a third electrical contact pad 301 arranged on the second surface 207. A first and a second electrical contact pad are represented in FIG. 4. A corresponding representation in FIG. 3 has been omitted for the sake of clarity.

The third electrical contact pad 301 electrically connects to an anode 303 of the blue laser diode 117. This electrical connection is formed by a bonding wire 305. The anode 303 can, therefore, be electrically contacted by electrical contacting of the third electrical contact pad 301.

The comments made in connection with the blue laser diode 117 with reference to FIG. 3 apply similarly for the red and green laser diodes 113, 115. Here as well, corresponding first and second and third electrical contact pads are provided for the purpose of electrical contacting.

FIG. 4 shows a contacting possibility between a subcarrier 401 and a mounting face (not shown here) of a carrier. The comments made in connection with FIG. 4 apply, for example, for the optoelectronic lamp device 101. The example represented in FIG. 4 may thus, for example, be provided in the optoelectronic lamp device 101. This thus means that the subcarrier 401 may, for example, be one of the subcarriers 107, 109, 111. The subcarriers 107, 109, 111 may be configured in a similar way to the subcarrier 401.

The subcarrier 401 has a first surface 403 facing toward the mounting face in the mounted state. The subcarrier 401 has a second surface 405 extending perpendicularly to the first surface 403. A laser diode 411 is arranged on the second surface 405. In this case, the laser diode 411 is arranged on the second surface 405 such that its fast axis extends parallel to the first surface 403, and therefore parallel to the planar mounting face of the carrier in the mounted state.

Reference 407 indicates a symbolically represented layer arrangement applied on the first surface 403. This layer arrangement 407 has an electrical contacting function, and is thus at least partially electrically conductive. For example, the layer arrangement 407 comprises a solder. In particular, the layer arrangement 407 comprises an adhesion or fastening function, so that the subcarrier 401 is fastened on the mounting face by means of the layer arrangement 407. The layer arrangement 407 thus comprises, in particular, a plurality of layers which have functionalities corresponding to those mentioned above.

Reference 409 likewise indicates a layer arrangement applied on the second surface 405. The laser diode 411 is arranged on this layer arrangement 409. The layer arrangement 409 has in particular an insulating function so that the laser diode 411 is electrically insulated from the subcarrier 401 by the layer arrangement 409. In particular, the layer arrangement 409 has an adhesion or fastening function so that the laser diode 411 is fastened on the second surface 405 by the layer arrangement 409. For example, the layer arrangement 409 comprises a solder. The layer arrangement 409 furthermore comprises an electrical contacting function so that electrical contacting of the laser diode 411, in particular of the cathode (not shown) of the laser diode 411, is made possible by the layer arrangement 409. The layer arrangement 409 thus comprises, in particular, a plurality of layers which have functionalities corresponding to those mentioned above.

FIG. 4 furthermore shows a first electrical contact pad 413 and a second electrical contact pad 415. These two electrical contact pads 413, 415 are arranged on the carrier, in particular on the mounting face. Electrical contacting of the laser diode 411 is made possible via these electrical contact pads 413, 415. Thus, a solder ball 419 is provided that electrically connects the second electrical contact pad 415 electrically to the layer arrangement 409 so that an electrical connection to the cathode of the laser diode 411 is formed.

A solder ball 419 is provided, which forms an electrical connection between the first electrical contact pad 413 and a third electrical contact pad 417. This third electrical contact pad 417 is arranged on the layer arrangement 409, but is electrically insulated therefrom to avoid or prevent an electrical short circuit. This third electrical contact pad 417 electrically connects by a bonding wire 423 to the anode 421 of the laser diode 411. Electrical contacting of the anode 421 of the laser diode 411 by means of the first electrical contact pad 413 is therefore made possible.

Reference 425 indicates a double arrow intended to represent a height of the laser diode 411 in relation to the first surface 403. Reference 427 indicates a double arrow intended to symbolically represent an edge distance between the laser diode 411 and an edge 429 of the second surface 405. Reference 431 indicates a double arrow intended to symbolically represent a width of the subcarrier 401.

We thus provide, in particular, a 90°-rotated mounting of a laser diode, in particular of a laser chip, in combination with two cylindrical lenses. The 90°-rotated mounting relates to the previously conventional mounting of laser diodes on a mounting face or on a subcarrier, according to which previously conventional type of mounting the fast axis extends perpendicularly to the mounting face, i.e. in the z direction according to the Cartesian coordinate system 119. The laser diode is thus rotated through 90° relative to this type of mounting, so that its fast axis now lies parallel to the x,y plane.

A functionality of the collimation may be divided between two cylindrical lenses, in general between a first collimator and a second collimator, which are thus respectively used or employed for slow axis collimation (SAC) and fast axis collimation (FAC). Because of a high divergence angle in relation to the fast axis, the first collimator, i.e., for example, the FAC cylindrical lens, in general already needs to be mounted very close to the laser facet of the laser diode when using micro-optics. Because of the rotation of the laser diodes, the fast axis now lies parallel to the x,y plane, i.e. to the mounting face. The first collimator, for example,. the FAC lens, in particular the FAC cylindrical lens, can thus be aligned in a planar (i.e. in the x,y plane) adjustment process which is much simpler to implement, compared to the conventional type of mounting in which the fast axis extends perpendicularly to the x,y mounting face.

Therefore, the advantage is achieved of an adjustment process, which is much simpler to implement, of the optics used, i.e. of the collimators, relative to the laser beam, i.e. to the laser radiation. The problem of height adjustment is therefore shifted by rotation of the laser diode through 90° compared to the previously conventional type of mounting, to the SAC lens, in general to the second collimator, for example, to the second cylindrical lens. For this, however, tolerance requirements are much easier to satisfy than for the first collimator, i.e., for example, in the FAC lens. In general, the SA (slow axis) divergence angle of a laser diode is much less than the FA (fast axis) divergence angle (generally by a factor of from 2 to 5). If the target of a circular spot after collimation by the two collimators is assumed, there is a correspondingly greater distance of the SAC (slow axis collimation) from the laser facet (i.e. a greater distance of the laser radiation relative to the laser facet) so that the tolerance requirements are reduced by the same factor.

A second factor added thereto according to another example, is better adjustability of a height of the laser facet above the mounting platform, i.e. above the mounting face. This is because a subcarrier, for example, a submount is provided in this example. The laser chip, in general the laser diode, may therefore advantageously be mounted with much higher precision on the subcarrier before the subcarrier is mounted on the platform, i.e. on the mounting face.

To mount the subcarrier, according to one example, it is provided that a solder process is used. This thus means that, according to one embodiment, the subcarrier is soldered onto the mounting face, or respectively that the subcarrier is soldered onto the mounting face.

Electrical contacting between the laser diode and the mounting face or mounting platform may, for example, according to one example be achieved by using solder-jet technology, i.e. by solder-jet processes (cf. FIG. 4 and the corresponding comments).

According to one example, the first collimator and the second collimator are micro-optics. According to one example, the first collimator and the second collimator are mounted on the mounting face by thin-film laser-beam soldering. This thus means that, for example, the micro-optical FAC and SAC lenses, in particular the FAC and SAC cylindrical lenses, can be mounted very rapidly by thin-film laser-beam soldering.

Although devices have been illustrated and described in detail by the preferred examples, this disclosure is not restricted by the examples disclosed and other variants may be derived therefrom by those skilled in the art without departing from the protective scope of the appended claims.

This application claims priority of DE 10 2015 105 807.3, the subject matter of which is incorporated herein by reference.

1.-10. (canceled)

11. An optoelectronic lamp device, comprising:
a carrier having a planar mounting face,
at least one laser diode that emits laser radiation, wherein
the laser diode has a fast axis and a slow axis,
the laser diode is arranged on the mounting face such that the fast axis is formed extending parallel to the mounting face,
a first collimator is provided for collimating laser radiation polarized in the direction of the fast axis, and
a second collimator is provided for collimating laser radiation polarized in the direction of the slow axis,
wherein, in the beam path of the laser radiation emitted by the laser diode, the first collimator is arranged proximally and the second collimator is arranged distally relative to the laser diode so that
the laser radiation polarized in the direction of the fast axis can be collimated first, and only then can the laser radiation polarized in the direction of the slow axis be collimated.

12. The optoelectronic lamp device as claimed in claim 11, wherein the first collimator and/or the second collimator are respectively configured as a collimator lens or a cylindrical lens.

13. The optoelectronic lamp device as claimed in claim 11, wherein the laser diode is arranged on a subcarrier, which is arranged on the mounting face so that the laser diode is arranged indirectly on the mounting face by the subcarrier.

14. The optoelectronic lamp device as claimed in claim 13, wherein the subcarrier has a first surface facing toward the mounting face, and the laser diode is arranged on a second surface of the subcarrier, which surface is formed perpendicularly to the first surface.

15. The optoelectronic lamp device as claimed in claim 13, wherein the subcarrier has a first surface facing toward the mounting face, the laser diode is arranged on a second surface of the subcarrier, which surface is formed perpendicularly to the first surface, and a first electrical contact pad and a second electrical contact pad are formed on the carrier, perpendicularly to the second surface, these contact pads being electrically connected respectively to an anode and to a cathode of the laser diode.

16. The optoelectronic lamp device as claimed in claim 13, wherein the subcarrier has a first surface facing toward the mounting face, the laser diode is arranged on a second surface of the subcarrier, which surface is formed perpendicularly to the first surface, wherein a first electrical contact pad and a second electrical contact pad are formed on the carrier, perpendicularly to the second surface, these contact pads being electrically connected respectively to an anode and to a cathode of the laser diode, a third electrical contact pad electrically connected to an anode or to a cathode is arranged on the second surface, the third electrical contact pad being electrically connected to the first or second electrical contact pad.

17. The optoelectronic lamp device as claimed in claim 11, wherein deviating optics that deviate laser radiation collimated by the second collimator are arranged in the beam path.

18. The optoelectronic lamp device as claimed in claim 11, wherein a red laser diode, a green laser diode and a blue laser diode are provided with respectively assigned first and second collimators so that an RGB laser source is formed.

19. The optoelectronic lamp device as claimed in claim 11, wherein the first collimator and the second collimator are configured as a common collimator component.

20. The optoelectronic lamp device as claimed in claim 19, wherein opposite end faces of the collimator component are respectively configured as a cylindrical lens and are rotated by about 90° degrees relative to one another.
